(19) United States
(12) Patent Application Publication
(10) Pub. No.: US 2014/0190402 A1
(43) Pub. Date: Jul. 10, 2014

(54) APPARATUS AND METHOD FOR MANUFACTURING INGOT

(71) Applicant: Dong Geun Shin, Seoul (KR)

(72) Inventor: Dong Geun Shin, Seoul (KR)

(73) Assignee: LG INNOTEK CO., LTD., Seoul (KR)

(21) Appl. No.: 14/123,325

(22) PCT Filed: Jun. 1, 2012
(86) PCT No.: PCT/KR2012/004343

§ 371 Date: Mar. 13, 2014

(30) Foreign Application Priority Data
Jun. 1, 2011 (KR) 10-2011-0053029

(51) Int. Cl. C30B 23/02

(52) U.S. Cl. CPC C30B 23/025
USPC 117/106; 118/726

(57) ABSTRACT

Disclosed are an apparatus and a method for fabricating an ingot. The apparatus includes a crucible receiving source materials therein; a holder fixing a seed located above the source materials; and an adhesive layer interposed between the holder and the seed and chemically bonded to the seed.

### TECHNICAL FIELD

The embodiment relates to an apparatus and a method for fabricating an ingot.

### BACKGROUND ART

In general, materials are very important factors to determine the property and the performance of final products in the electric, electronic and mechanical industrial fields.

Among the materials, SiC represents the superior thermal stability and superior oxidation-resistance property. In addition, the SiC has the superior thermal conductivity of about 4.6 W/Cm° C., so the SiC can be used for fabricating a large-size substrate having a diameter of about 2 inches or above. In particular, the single crystal growth technology for the SiC is very stable in the art, so the SiC has been extensively used in the industrial field as a material for a substrate.

### DISCLOSURE OF INVENTION

### Technical Problem

The embodiment provides an apparatus and a method for fabricating an ingot having a large size and reduced defects.

### Solution to Problem

An apparatus for fabricating an ingot according to the embodiment includes a crucible receiving source materials therein; a holder fixing a seed located above the source materials; and an adhesive layer interposed between the holder and the seed and chemically bonded to the seed.

A method for fabricating an ingot according to the embodiment includes the steps of forming a preliminary adhesive layer including silicon between a holder and a seed; forming an adhesive layer chemically bonded to the seed by heating the preliminary adhesive layer; and growing a silicon carbide crystal on the seed by using source materials including silicon and carbon.

### Advantageous Effects of Invention

The apparatus for fabricating the ingot according to the embodiment includes the adhesive layer chemically bonded with the seed, so the seed can be securely bonded to the holder. Thus, the ingot can be prevented from being delaminated from the holder when the ingot is grown on the seed.

Therefore, the apparatus according to the embodiment can fabricate the ingot having the large size.

In addition, the adhesive layer may include the compound of silicon and carbon. In particular, the adhesive layer may have the composition similar to that of the seed. Thus, the adhesive layer has a dense structure, so that the seed and the ingot can be effectively protected. Especially, the adhesive layer can prevent the defect transition from the holder to the ingot.

Therefore, the apparatus for fabricating the ingot according to the embodiment can provide the ingot having the high quality.

### BRIEF DESCRIPTION OF DRAWINGS

FIG. 1 is a sectional view showing an apparatus for fabricating an ingot according to the embodiment;

FIG. 2 is a sectional view showing a seed, a holder and an adhesive layer;

FIGS. 3 to 7 are sectional views showing the procedure for bonding a seed to a holder; and

FIG. 8 is a sectional view showing the procedure for forming an ingot.

### MODE FOR THE INVENTION

In the description of the embodiments, it will be understood that when a layer (film), a region, a pattern or a structure is referred to as being “on” or “under” another layer (film), another region, another pattern or another structure, it can be “directly” or “indirectly” on the other layer (film), region, pattern, or structure, or one or more intervening layers may also be present. Such a position has been described with reference to the drawings.

The thickness and size of each layer (film), each region, each pattern or each structure shown in the drawings may be exaggerated, omitted or schematically drawn for the purpose of convenience or clarity. In addition, the size of elements does not utterly reflect an actual size.

Hereinafter, exemplary embodiments will be described with reference to accompanying drawings.

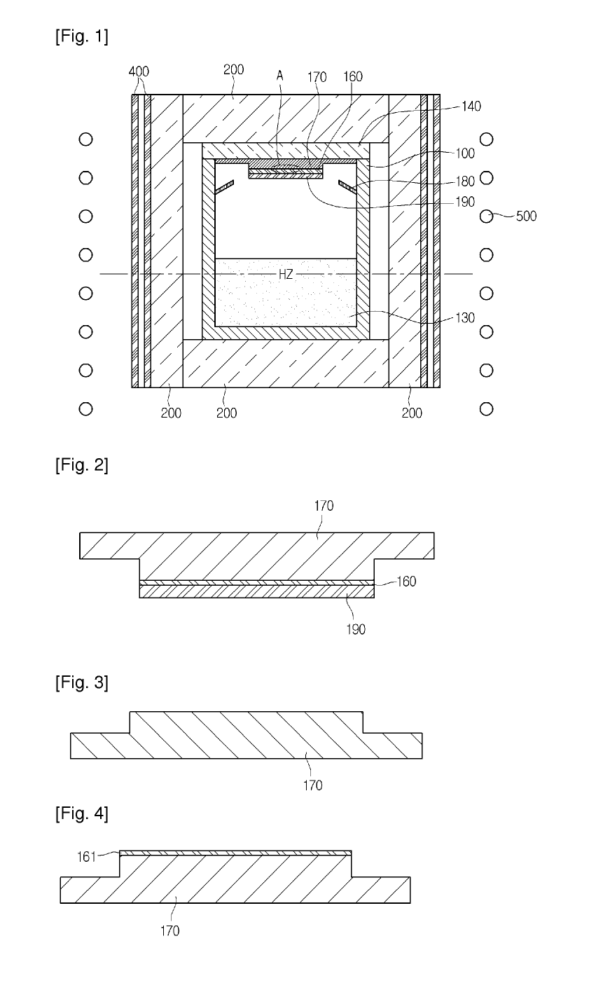

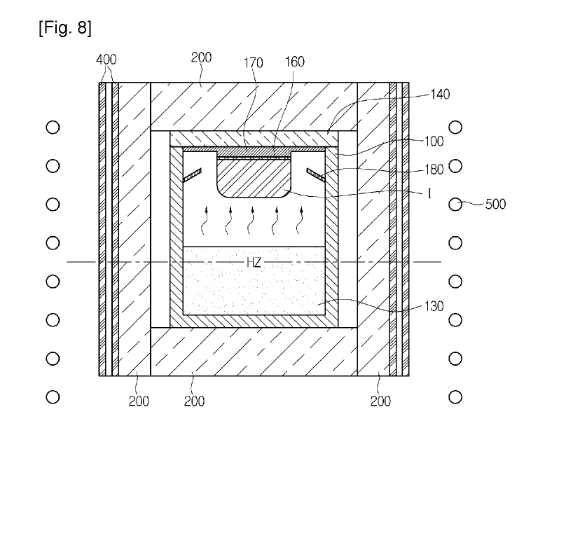

FIG. 1 FIG. 1 is a sectional view showing an apparatus for fabricating an ingot according to the embodiment, FIG. 2 is a sectional view showing a seed, a holder and an adhesive layer, FIGS. 3 to 7 are sectional views showing the procedure for bonding the seed to the holder, and FIG. 8 is a sectional view showing the procedure for forming the ingot.

Referring to FIGS. 1 and 2, the apparatus for fabricating the ingot includes a crucible 100, a top cover 140, a seed holder 170, an adhesive layer 160, a focusing tube 180, an adiabatic material 200, a quartz tube 400 and a heat induction part 500.

The crucible 100 contains source materials 130 therein. The source materials 130 may include silicon and carbon. In detail, the source materials 130 may include a silicon carbide (SiC) compound. The crucible 100 may contain SiC power or polycarbosilane therein.

The crucible 100 has a cylindrical shape to contain the source materials 130.

The melting point of the material used for the crucible 100 is higher than the sublimation temperature of the SiC. For instance, the crucible 100 can be manufactured by using graphite.

In addition, the crucible 100 can be manufactured by coating a material having the melting point higher than the sublimation temperature of the SiC on the graphite. Preferably, a material, which is chemically inert with respect to silicon and hydrogen in the growth temperature for the SiC single crystal, is used as the material coated on the graphite. For instance, the material may include carbide or nitride based ceramic. In particular, a ceramic including at least two of Ta, Hf, Nb, Zr, W and V and carbide including carbon can be coated on the graphite. Further, a mixture including at least two of Ta, Hf, Nb, Zr, W and V and nitrogen can be coated on the graphite.

A top cover 140 is placed on the crucible 100. The top cover 140 can seal the crucible 100. In detail, the top cover 140 seals the crucible 100 such that a reaction may occur in the crucible 100.

The top cover 140 may include graphite, but the embodiment is not limited thereto. For instance, the top cover 140 may include a material having the melting point higher than the sublimation temperature of the SiC.

The seed holder 170 is located under the top cover 140. The seed holder 170 is fixed to the underside of the top cover 140. The seed holder 170 may be detachably attached to the top cover 140. In addition, the seed holder 170 is disposed above the source materials 130.

The seed holder 170 may fix a seed 190. In addition, the seed holder 170 supports the seed 190. The seed 190 is disposed below the seed holder 170.

The seed 190 includes silicon carbide. In detail, the seed 190 includes single crystal silicon carbide. The seed 190 has a circular plate shape but the embodiment is not limited thereto.

The seed holder 170 may include high-density graphite. The seed holder 170 has a bottom surface corresponding to a top surface of the seed 190. The bottom surface of the seed holder 170 is flattened.

The seed holder 170 may include a plurality of fine pores 171. In particular, the fin pores 171 can be formed in the bottom surface of the seed holder 170.

The adhesive layer 160 is formed under the seed holder 170. In detail, the adhesive layer 160 is interposed between the seed holder 170 and the seed 190. The adhesive layer 160 is placed to the seed holder 170. The adhesive layer 160 is bonded to the bottom surface of the seed holder 170. In addition, a part of the adhesive layer 160 can be inserted into the pores 171 of the seed holder 170. Thus, the adhesive layer 160 can be securely bonded to the seed holder 170.

The adhesive layer 160 may have a thickness in a range of about 0.1 μm to about 10 μm.

In addition, the adhesive layer 160 contains silicon. In detail, the adhesive layer 160 includes a compound of silicon and carbon. In more detail, the adhesive layer 160 may include silicon carbide. For instance, the adhesive layer 160 can be expressed as following chemical formula 1.

Chemical Formula 1

Si_{X}C_{Y}(0<X<1,0<Y<1)

In addition, the adhesive layer 160 can be chemically bonded to the seed 190. That is, a material of the adhesive layer 160 can be chemically bonded to a material of the seed 190.

Therefore, the seed 190 can be securely bonded to the adhesive layer 160. As a result, the seed 190 can be securely fixed to the seed holder 170.

In addition, since the adhesive layer 160 includes the compound of silicon and carbon, the adhesive layer 160 may have a structure similar to that of the seed 190. Thus, the adhesive layer 160 can be tightly bonded to the seed 190, so that the adhesive layer 160 has a dense structure.

Therefore, the adhesive layer 160 can prevent the defect transition from the seed holder 170 to the seed 190. That is, the adhesive layer 160 may serve as a protective layer for preventing the defect transition to the ingot.

Further, since the adhesive layer 160 includes the compound of silicon and carbon, the adhesive layer 160 may have the thermal expansion coefficient substantially similar to that of the seed 190. Thus, the defect caused by the difference of the thermal expansion coefficient between the seed holder 170 and the seed 190 can be diminished. In addition, the delamination of the seed 190 caused by the difference of the thermal expansion coefficient can be prevented during the single crystal growth process.

The focusing tube 180 is located in the crucible 100. The focusing tube 180 may be located at a region where the single crystal is grown. The focusing tube 180 narrows a path of sublimated SiC gas to concentrate the sublimated SiC gas onto the seed 190. Thus, the growth rate of the single crystal may be improved.

The adiabatic material 200 surrounds the crucible 100. The adiabatic material 200 keeps the temperature of the crucible 100 to the level of the crystal growth temperature. Since the crystal growth temperature of the SiC is high, graphite felt may be used as the adiabatic material. In detail, the adiabatic material 200 can be prepared by compressing graphite fiber in the form of a cylinder having a predetermined thickness.

In addition, the adiabatic material 200 may be prepared as a plurality of layers surrounding the crucible 100.

The quartz tube 400 is positioned at an outer peripheral surface of the crucible 100. The quartz tube 400 is fitted into the outer peripheral surface of the crucible 100. The quartz tube 400 may block heat transferred to a single crystal growth apparatus from the heat induction part 500. The quartz tube 400 is a hollow tube and cooling water may circulate through an inner space of the quartz tube 400. Thus, the quartz tube 400 can precisely control the growth rate and growth side of the single crystal.

The heat induction part 500 is positioned outside the crucible 100. For instance, the heat induction part 500 is an RF induction coil. As RF current is applied to the RF induction coil, the crucible 100 can be heated. That is, the source materials contained in the crucible 100 can be heated to the desired temperature.

The center area of the heat induction part 500 is located below the center area of the crucible 100. Thus, the temperature gradient may occur at the upper and lower portions of the crucible 100. That is, the center area (hot zone; HZ) of the heat induction part 500 is located relatively lower than the center area of the crucible 100, so the temperature of the lower portion of the crucible 100 may be higher than the temperature of the upper portion of the crucible 100 on the basis of the hot zone HZ. In addition, the temperature may rise from the center of the crucible 100 to the outer peripheral portion of the crucible 100. Due to the temperature gradient, the SiC source materials may be sublimated so that the sublimated SiC gas moves to the surface of the seed 190 having the relatively low temperature. Thus, the SiC gas is recrystallized, so the SiC single crystal is grown.

The seed 190 can be bonded to the seed holder 170 through the following procedure.

Referring to FIG. 3, the seed holder 170 is prepared while being overturned. Thus, the bottom surface of the seed holder 170 is directed upward.

Referring to FIG. 4, a preliminary adhesive layer 161 is formed at the seed holder 170. The preliminary adhesive layer 161 is coated on the bottom surface of the seed holder 170 in the form of a paste.

The preliminary adhesive layer 161 may include silicon polymer. In detail, the preliminary adhesive layer 161 may include polymer having the —Si—C-bonding structure. The preliminary adhesive layer 161 may include carbosilane polymer(polymer composed of carbon and silicon in the backbone structure).

In detail, the polycarbosilane polymer may include one selected from the group consisting of allylhydrido polycarbosilane (AHPCS), polycarbosilane (PCS) and polyphenylcarbosilane (PPCS). The AHPCS, PCS and PPCS may have chemical formulas as follows.

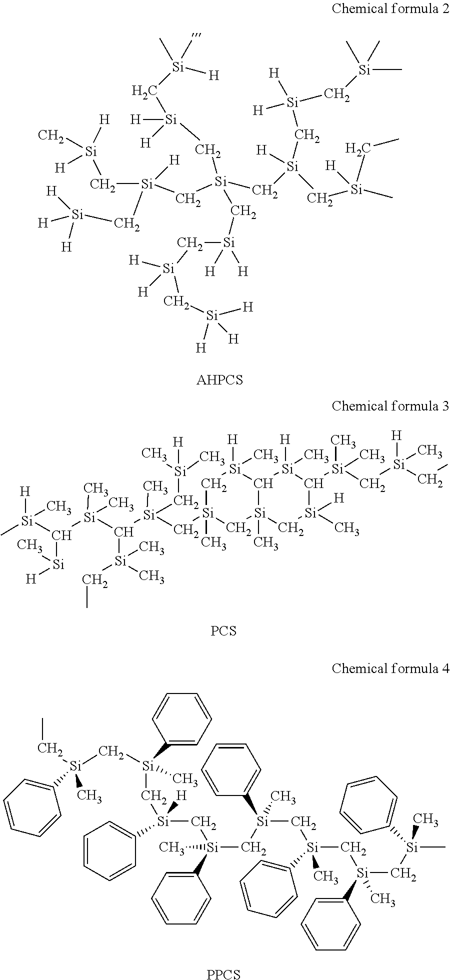

In addition, the average molecular weight of the carbosilane polymer to form the preliminary adhesive layer 161 is about 1500 to about 5000, and the molecular weight distribution of the carbosilane polymer is about 1.0 to about 2.0. In particular, the carbosilane polymer may have the superior adhesive force when the average molecular weight is about 3000 to about 5000, and the molecular weight distribution is closer to 1.0.

In addition, the carbosilane polymer to form the preliminary adhesive layer 161 may be dissolved in an organic solvent, such as toluene or hexane. Thus, the solution mixed with the carbosilane polymer can be prepared in the form of a paste having a predetermined viscosity.

The carbosilane polymer is mixed with the organic solvent in the rate of about 10 wt % to about 50 wt %. In detail, the carbosilane polymer is mixed with the organic solvent in the rate of about 20 wt % to about 40 wt %. For instance, if the carbosilane polymer is AHPCS, the carbosilane polymer is mixed with the organic solvent in the rate of about 20 wt % to about 30 wt %. In addition, if the carbosilane polymer is PCS, the carbosilane polymer is mixed with the organic solvent in the rate of about 20 wt % to about 40 wt %. Further, if the carbosilane polymer is PPCS, the carbosilane polymer is mixed with the organic solvent in the rate of about 20 wt % to about 40 wt %.

The paste may have the viscosity of about 100 cp to about 30000 cp. In detail, the paste may have the viscosity of about 3000 cp to about 5000 cp. If the paste has the above viscosity, the paste can be properly bonded to the seed holder 170 and to the seed holder 190.

That is, the carbosilane polymer may be prepared as the paste to form the preliminary adhesive layer 161 or may be dissolved in the organic solvent to form the paste. The paste is uniformly coated on the seed holder 170 to form the preliminary adhesive layer 161.

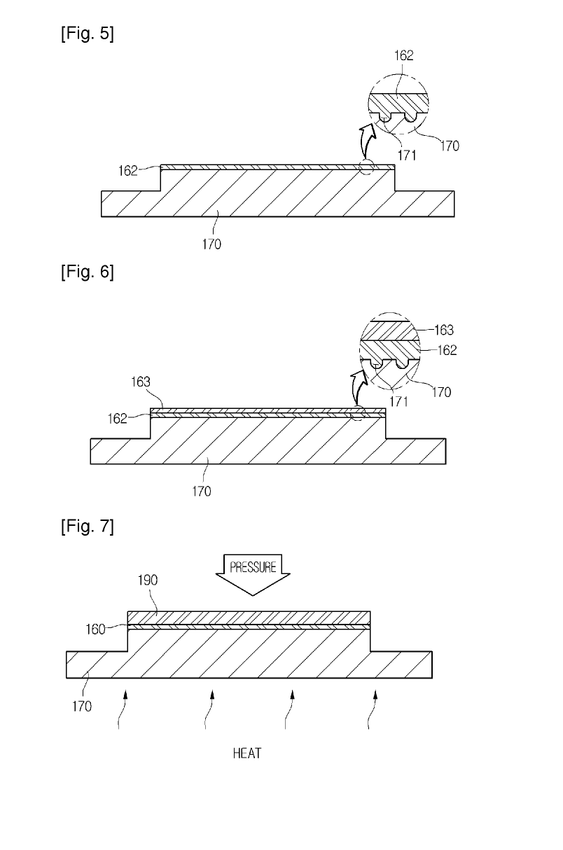

As shown in FIGS. 5 and 6, the preliminary adhesive layer 161 may include two layers 162 and 163.

First, first and second pastes having viscosity different from each other are formed. The first paste may have the viscosity lower than that of the second paste. That is, the first paste may include a greater amount of organic solvents as compared with the second paste. In detail, the first paste may have the viscosity in the range of about 100 cp to about 2000 cp and the second paste may have the viscosity in the range of about 3000 cp to about 5000 cp.

In addition, the first paste may include the carbosilane polymer in the rate of about 10 wt % to about 25 wt % based on the organic solvent and the second paste may include the carbosilane polymer in the rate of about 30 wt % to about 50 wt % based on the organic solvent.

Referring to FIG. 5, the first paste is coated on the bottom surface of the seed holder 170 to form the preliminary adhesive layer 161. Since the first paste has relatively lower viscosity, the first paste may be easily filled in the pores 171 of the seed holder 170.

Referring to FIG. 6, the second paste is coated on the first preliminary adhesive layer 162. Thus, the second preliminary adhesive layer 163 is formed on the first preliminary adhesive layer 162. Since the second paste has relatively high viscosity, the second paste can be coated on the first paste with a heavy thickness.

That is, since the preliminary adhesive layer includes two preliminary adhesive layers 162 and 163 having the viscosity different from each other, the silicon polymer can be easily filled in the pores 171 of the seed holder 170.

Referring to FIG. 7, the seed 190 is disposed on the preliminary adhesive layer 161. Then, pressure is applied to the seed 190 and heat is applied to the preliminary adhesive layer 161. Thus, the carbosilane polymer contained in the preliminary adhesive layer 161 is converted into the SiC compound, so that the adhesive layer 160 is formed.

At this time, the adhesive layer 160 is chemically bonded to the seed 190. That is, the materials contained in the preliminary adhesive layer 161 are converted into the structure similar to the structure of the materials contained in the seed 190 during the heat treatment process, so the materials contained in the preliminary adhesive layer 161 are chemically bonded to the materials contained in the seed 190. In addition, hydrogen contained in the preliminary adhesive layer 161 can be discharged in the form of hydrogen gas.

The seed 90 may be pressed by a weight or uniform pressure. Thus, the uniform pressure may be applied to the preliminary adhesive layer 161.

The heat treatment process for the preliminary adhesive layer 161 may be performed through two steps. First, the preliminary adhesive layer 161 is heat-treated for about 30 minutes to about 3 hours in the temperature of about 500° C. to about 800° C. Thus, the carbosilane polymer contained in the preliminary adhesive layer 161 is decomposed into inorganic phase.

Then, the preliminary adhesive layer 161 is secondarily heat-treated for about 1 hour to about 10 hours in the temperature of about 1200° C. to about 1600° C. Thus, the decomposed layer is sintered forms the Si—C compound layer. In detail, the adhesive layer 160 including the silicon carbide is formed.

Referring to FIG. 8, the seed holder 170 bonded with the seed 190 is covered with the top cover 200.

Then, the source materials 130 contained in the crucible 100 are heated, so that silicon and carbon contained in the source materials 130 are sublimated. Due to the sublimation of the silicon and carbon, the ingot I including the single crystal silicon carbide is grown on the seed 190.

As described above, since the seed 190 is chemically bonded to the adhesive layer 160, the ingot I may be prevented from being delaminated from the seed holder 170 when the ingot I is growing on the seed 190.

Thus, the apparatus according to the embodiment may fabricate the ingot having a large size.

In addition, since the adhesive layer 160 includes the Si—C compound and has the composition similar to that of the seed 190, the adhesive layer 160 may have the dense structure and can effectively protect the ingot. In particular, the adhesive layer 160 can prevent the defect transition from the seed holder 170 to the ingot.

Therefore, the apparatus for fabricating the ingot according to the embodiment can provide the ingot having the high quality.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An apparatus for fabricating an ingot, the apparatus comprising:
a crucible containing source materials therein;
a holder fixing a seed located above the source materials; and
an adhesive layer interposed between the holder and the seed and chemically bonded to the seed.

2. The apparatus of claim 1, wherein the adhesive layer includes a compound of silicon and carbon.

3. The apparatus of claim 2, wherein the holder includes the carbon and the seed includes silicon carbide.

4. The apparatus of claim 1, wherein the adhesive layer has a thickness of about 0.1 μm to about 10 μm.

5. The apparatus of claim 1, wherein the holder includes a plurality of pores, and a part of the adhesive layer is filled in the pores.

6. The apparatus of claim 1, wherein the adhesive layer includes silicon carbide.

7. A method for fabricating an ingot, the method comprising:
forming a preliminary adhesive layer including silicon between a holder and a seed;
forming an adhesive layer chemically bonded to the seed by heating the preliminary adhesive layer; and
growing a silicon carbide crystal on the seed by using source materials including silicon and carbon.

8. The method of claim 7, wherein the preliminary adhesive layer includes polymer having a bonding structure of silicon and carbon.

9. The method of claim 7, wherein the preliminary adhesive layer includes carbosilane polymer.

10. The method of claim 7, wherein the carbosilane polymer includes one selected from the group consisting of allylhydrido polycarbosilane, polycarbosilane and polyphenylcarbosilane).

11. The method of claim 7, wherein the forming of the preliminary adhesive layer comprises:
forming a paste by mixing carbosilane polymer with a solvent; and
coating the paste onto the holder.

12. The method of claim 11, wherein the carbosilane polymer is mixed with the solvent in a rate of 10 wt % to 50 wt %.

13. The method of claim 11, wherein the forming of the paste comprises:
forming a first paste and a second paste having viscosity higher than viscosity of the first paste by mixing the carbosilane polymer with the solvent, and
the forming of the preliminary adhesive layer comprises:
forming a first preliminary adhesive layer by coating the first paste onto the holder; and
forming a second preliminary adhesive layer by coating the second paste onto the first preliminary adhesive layer.

14. The method of claim 13, wherein the holder is formed with a plurality of pores and the first paste is filled in the pores.
